(19) United States
(12) Patent Application Publication
(10) Pub. No.: US 2006/0070870 A1
(43) Pub. Date: Apr. 6, 2006

(54) Flexible extruded plastic profile, especially plastic tube and method for producing the same

(75) Inventors: Thomas Schettler, Rehau (DE); Alexander Oelschlegel, Konradsreuth (DE)

Correspondence Address: VENABLE LLP, P.O. BOX 34385, WASHINGTON, DC, 20045-9998, US

(73) Assignee: REHAU AG & CO., Rehau (DE)

(21) Appl. No.: 11/285,350

(22) Filed: Nov. 23, 2005

Related U.S. Application Data
(62) Division of application No. 10/480,101, filed on Dec. 8, 2003.

(30) Foreign Application Priority Data
Jun. 12, 2001 (DE) 101 28 332.6

(51) Int. Cl. C23C 14/00; C23C 14/32; B05D 1/36; B05D 7/00

(52) U.S. Cl. 204/192.15; 427/402; 204/192.38

(57) ABSTRACT

A method for making the plastic profile comprising depositing an inner thin film with a metallic appearance onto the surface of the flexible extruded plastic profile depositing an outer protective cover layer that is at least partially transparent onto the inner thin film wherein the inner thin film and the outer protective cover layer form a layer system to cover the flexible extruded plastic profile.

### CROSS-REFERENCE TO RELATED APPLICATIONS

This application is a divisional of U.S. application Ser. No. 10/480,101 filed Dec. 8, 2003, which is a national stage application of PCT/EP02/05646 filed May 23, 2002, which claims the priority of German Patent Application No. 101 28 332.6 filed Jun. 12, 2001. The foregoing documents are incorporated herein by reference in their entirety.

### BACKGROUND OF THE INVENTION

The invention relates to a flexible extruded plastic profile, in particular a plastic tube, with an outer surface having a dyed and/or metallized appearance.

An extruded plastic profile of this type in the form of a plastic tube, especially a sanitary tube, is known from European Patent EP 0 685 675 B1. The outer surface of the plastic tube described therein is dyed or has a metallic appearance, which is achieved by applying a hot-stamped foil containing the dye and/or metallizing to the tube. A transparent tube foil is then extruded onto this hot-stamped foil to provide a protective cover. The hot-stamped foil itself is applied by preferably winding it spirally around the tube, either by means of an essentially continuous pushing operation, wherein the abutting edges are glued or welded together, or by means of an overlapping, spiral impressing of the hot-stamped foil, which is also conceivable. In addition to the spiral-type application of the foil, a longitudinal arrangement of several parallel hot-stamped foil bands that abut or overlap is possible as well.

However, a plastic tube of this type is very expensive to produce. In addition, the outside appearance is not uniform, which is caused on the one hand by the pushed-together edges that are always visible to some degree and, on the other hand, by the circumstance that when the tube is in use, meaning if it is bent or turned because of its flexibility, the dyed or metallized layer shows fine cracks, meaning the complete dyed or metallized layer exhibits a structure or pattern of minute cracks. This results in losses in the optics, in particular the brilliance of the tube, which is intended to look like a metallic or chromium-plated tube, particularly in the case of a metallizing.

### BRIEF SUMMARY OF THE INVENTION

Thus, the invention is based on the problem definition of providing a flexible extruded plastic profile which does not have the above-mentioned disadvantages and has an optically appealing outer surface.

The invention solves this problem for an extruded plastic profile of the aforementioned type by providing the profile outside with a layer comprising an inner thin film with a metallic appearance and an outer, at least partially transparent protective layer.

The extruded plastic profile according to the invention advantageously distinguishes itself through the use of a layer system, meaning individual layers are applied to the profile and/or are deposited thereon. Thus, the invention dispenses with the possible application of foils or the like. Rather, it advantageously provides a multi-layer system comprising separately deposited layers. The inner thin film with metallic appearance achieves the actual decorative effect. The protective layer prevents damage to the thin film when the extruded plastic profile is in use. The problems described in the prior art do not even come up as a result of the deposit of uniform, self-contained layers. On the one hand, it is easier to deposit layers than apply hot-stamped foil, which must be wound in an involved operation or otherwise be pressed on. On the other hand, no seams or edges or the like are created which would influence the optics in a disadvantageous manner. Finally, we are dealing with a thin film having a metallic appearance, preferably with a thickness of 5 μm and in particular 3 μm. A thin film of this type is extremely flexible and does not have a tendency to tear even if subjected to high stresses, so that no cracks or the like will appear, not even in the case of frequent or extreme use of the extruded plastic profile.

The metallic appearance of the inner thin film can be created either as a result of its own color or through the effects of light interference.

The layer can be a metallic layer, such as a vapor-deposited chromium layer or the like. In the same way, it is also possible to deposit a metal-containing layer, wherein a metal-compound layer is advantageously used for this, e.g. in the form of a metal nitride, a metal carbon nitride or a metal oxide. However, this list is not complete since any type of metal compound can be used, which can be deposited in any optional form and offers a metallic appearance. We must point out here that “having a metallic appearance” can refer to the layer having a glossy metallic effect, but can also refer to a dull metallic appearance.

As previously described, it is particularly useful if the thin film is deposited by means of a depositing technique. Any depositing technique can conceivably be used, which permits the creation of a thin, inherently self-contained and pore-free layer. As examples, we want to mention here the techniques of chemical metallizing, galvanic coating, depositing of preferably metallic micro-particles, vacuum evaporation such as sputtering, thermal vapor-deposit, light-arc vapor depositing.

The thin film can be provided over the complete surface or a part of the surface, depending on the concrete outer appearance that is desired for the extruded plastic profile. By using suitable method-typical steps for depositing the thin film with metallic appearance, a partial covering of the profile body can also be achieved, which allows creating markings, e.g. in the form of emblems or writing strokes that are subsequently visible through the transparent protective layer.

According to the invention, the protective layer can be completely transparent, meaning it does not influence the optics and/or the appearance of the thin film. Alternatively, it is possible to use the protective cover layer to purposely influence the optics of the thin film. For example, it can have a transparent color, meaning the profile shows a colored metallic gloss or effect.

It is also possible for the protective layer to have a delustering effect, meaning it is partially transparent and the glossy thin film underneath, which is originally glossy, has a dull or mat appearance toward the outside. It is advantageous if the protective layer is light-resistant, especially UV resistant, to avoid that it will be damaged over time by light, e.g. becomes stained or cloudy, thereby resulting in damage to the outer appearance of the complete extruded plastic profile. It is furthermore important to avoid that especially the UV share of the light penetrates the protective cover layer and hits the thin film, which can thus be damaged as well.

A varnish layer or a two-component or multi-component varnish layer system can be deposited as protective layer, wherein an extruded layer, a pyrolysis layer or a polymerization layer can also be used. Each of these layer types is deposited by using a corresponding method that is typical for the type of material.

According to a modification of the inventive idea, the layer system furthermore can comprise an adhesion-promoting intermediate layer between the inner thin film and the protective cover layer. This intermediate layer is optional and is required only if no sufficient adhesion already exists between the inner thin film and the protective cover layer as a result of the natural absorption characteristics of the contacting materials. The adhesion-promoting intermediate layer is extremely thin and is only designed to achieve a secure connection between the thin film and the protective cover layer. By itself, it does not effect the optics in any way.

According to a first embodiment of the invention, the intermediate layer can be a separately inserted and/or deposited intermediate layer, e.g. in the form of a primer layer applied by means of dipping or the like, or in the form of a polymerization layer. Alternatively, it is possible to create the intermediate layer by means of a mechanical, physical or chemical processing of the thin film surface. It is also conceivable to use physical or chemical etching, oxidation and fluoridation.

Important in this connection is the fact that each of the different methods of creating the intermediate layer does not or only insignificantly influence the optics of the thin metallic film. That is to say, a deposited glossy thin metallic film will be glossy despite an extremely thin (in the nm range) intermediate layer that is created through chemical etching, for example, so that the same optical characteristics desired after the protective cover layer is deposited can be achieved as are achieved without the intermediate layer.

In a further modification of the inventive idea, the layer system can comprise a base layer that is applied directly to the surface of the profile. This base layer serves to prepare the surface for the following coating with additional layers, for example, if the surface of the extruded plastic profile itself does not meet the requirements for a desirable surface structure. The base layer can be a varnish layer or a two-component or multi-component varnish layer system, wherein a polymer extrusion layer is conceivable as well. The varnish layer or the two-component or multi-component varnish layer system is usefully applied with a dipping technique. The same is also true for the protective cover layer, insofar as this layer comprises a varnish (system). The polymer extrusion layer can be applied, for example, through extrusion-encasing. The base layer can have an optional surface shape, which can be smooth, but can conceivably also have a structured surface.

Finally, according to one modification of the inventive idea, it can be provided that the layer system furthermore comprises an adhesion-promoting intermediate layer between the base layer and the inner thin film. This intermediate layer is also purely optional and must be provided only if the adhesion between the base layer and the inner thin film is not already sufficient as a result of the natural absorption or adhesion characteristics. Again, this can be a separately inserted intermediate layer, e.g. in the form of a primer layer, preferably obtained through dipping, or a polymerization layer. Alternatively, it is also conceivable to use mechanical, physical or chemical steps for processing the surface of the thin film to create the intermediate layer.

The extruded plastic profile according to the invention thus comprises a multi-layer system which, in the simplest form, comprises at least two layers, namely the inner thin film and the protective outer layer that is deposited immediately thereon, up to a five-layer system comprising a base layer, an intermediate layer, an inner thin film, another intermediate layer and the covering protective layer. It is important that the material-technical characteristics of the individual layers must be correlated to each other or to the layer positioned respectively underneath in such a way that the stability of the compound layer is ensured for all relevant characteristics, particularly with respect to the optical, mechanical, chemical and physical requirements.

In addition to the extruded plastic profile itself, the invention furthermore relates to a method for producing a flexible extruded plastic profile, in particular a plastic tube of the above-described type. This profile distinguishes itself in that in order to form a layer system an inner thin film with a metallic appearance is initially deposited on the profile outside and that subsequently an outer, at least partially transparent protective cover layer is deposited thereon. In addition to these two layers, which are sufficient for the purpose of the simplest embodiment of the invention for producing an extruded plastic profile according to the invention, a base layer as well as adhesion-promoting intermediate layers between the base layer and the thin film and/or between the thin film and the protective layer can furthermore be deposited or created. These individual steps follow from the dependent claims.

Further advantages, features, and details of the invention follow from the exemplary embodiments described below, as well as the drawings.

### BRIEF DESCRIPTION OF THE DRAWINGS

FIG. 1 A sectional view of a first embodiment of an extruded plastic profile according to the invention;

FIG. 2 A sectional view of a second embodiment of an extruded plastic profile according to the invention;

FIG. 3 A sectional view of a third embodiment of an extruded plastic profile according to the invention, and

FIG. 4 A sectional view of a fourth embodiment of an extruded plastic profile according to the invention.

### DETAILED DESCRIPTION OF THE INVENTION

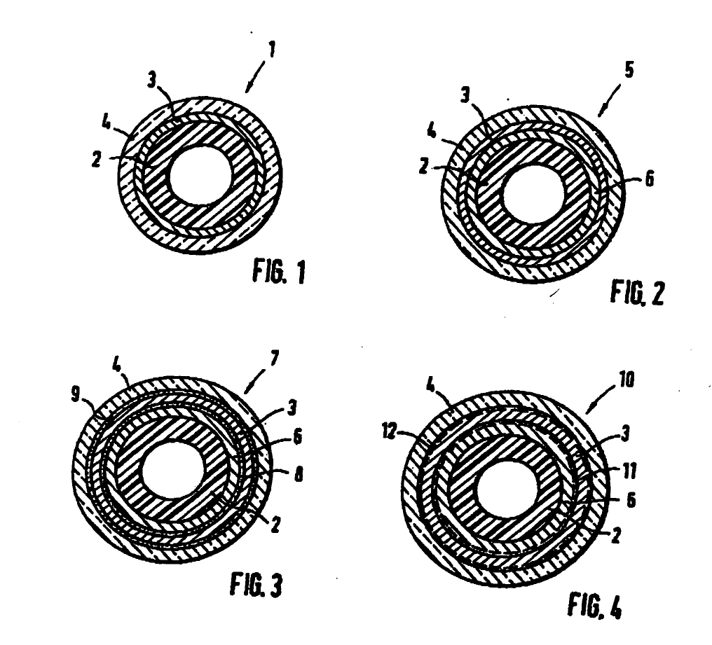

FIG. 1 shows a sectional view of a first embodiment of an extruded plastic profile 1 according to the invention. For the exemplary embodiment shown, this profile is a tube-shaped profile body 2, comprising a layer system deposited on its outside. In the simplest embodiment shown in FIG. 1, this layer system comprises an inner thin film 3 with metallic appearance, which is deposited on the profile body 2 and which advantageously can be a vapor-deposited metallic layer, wherein other depositing techniques are conceivable as well, e.g. the chemical metallizing and the galvanic coating and the like. Also, it is not necessary for a pure metal layer to be deposited. A metal-containing layer can conceivably be applied as well, provided this layer has a metallic appearance.

An outer protective cover layer 4 is subsequently deposited on the inner thin film, which can be completely transparent so that the underlying thin film with metallic appearance is visible completely and without influence. Alternatively, it is also conceivable that the protective cover layer 4 influences the optics of the thin film underneath to some degree, for example it can have a transparent coloring and result in an optionally colored and glossy outer appearance or the like instead of having a silver-colored outer appearance. Also, the protective cover layer 4 can be designed so as to have a delustering effect, etc.

Any optional layer which has sufficient flexibility and offers the required protective function can be used for the protective cover layer.

Varnish layers or components of varnish layer systems, applied with a simple dipping technique, as well as extrusion, pyrolysis or polymerization layers can conceivably be used.

As a result of the planar deposit of the inner thin film 3 in particular, a self-contained surface is obtained that offers a homogeneous view. The advantage of using a self-contained thin film is that it relates to a homogeneously deposited layer without any abutting edges and the like. This is particularly important for the total outer appearance of the layer system since the thin film with metallic appearance supplies the actual decorative effect. Of course, it is also conceivable to use a combination of thin films in place of a single thin film, meaning a thin-film system comprising multiple thin films is deposited which, however, is still covered by the term “thin film.”

Suitable materials for use are all material groups which can be deposited as thin films or thin-film combinations and can impart a metallic appearance because of their inherent color or as a result of light interference. Examples for this are metals or metal-compound layers.

FIG. 2 shows another embodiment of an extruded plastic profile 5 according to the invention. This embodiment also has a profile body 2. However, a base layer 6 is initially deposited on the profile body, which essentially serves to prepare the surface of the profile body 2 for the subsequent depositing of additional layers. This base layer can furthermore be a varnish layer or varnish layer system, preferably created with the dipping technique. An extruded polymer layer can conceivably be used as well, which is advantageously applied by means of extrusion encasing, wherein this list is also not complete. It is important that this layer is a securely adhering layer that is correlated with the mechanical characteristics of the profile body and in particular the elasticity to have sufficient adherence and which forms a good base for the subsequent compound layer.

The thin film 3 with metallic appearance is subsequently deposited on the base layer 6 and the protective cover layer 4 in turn is deposited on the thin film. In comparison to the embodiment according to FIG. 1, which shows only a two-layer system consisting of the thin film and the protective cover layer, the layer system according to FIG. 2 is a three-layer system consisting of the base layer, the thin film and the protective cover layer.

FIG. 3 shows another embodiment according to the invention of an extruded plastic profile 7. With this embodiment, a base layer 6 is applied to the profile body 2, in the same way as for the extruded plastic profile 6. An adhesion-promoting intermediate layer 8 in the form of a separate layer is then deposited on the base layer. This layer can be a primer layer, for example, or a polymerization layer. This adhesion-promoting intermediate layer is designed to provide sufficient adhesion between the base layer and the thin film 3 that is subsequently deposited on the intermediate layer 8, provided there is not already sufficient adhesion as a result of the natural absorption characteristics between the base layer 6 and the thin film 3.

Once the thin film 3 is deposited, a second adhesion-promoting intermediate layer 9 is deposited on the thin film 3, wherein this is also a separate intermediate layer for this embodiment, e.g. in the form of a primer or polymerization layer that is solely intended to have an adhesion-promoting effect. In particular, it should not have the effect of influencing the optics in any way. A protective cover layer 4 is subsequently deposited on the adhesion-promoting intermediate layer 9.

This embodiment relates to a five-layer system, consisting of the base layer 6, the first adhesion-promoting intermediate layer 8, the thin film 3, the second adhesion-promoting intermediate layer 9 and the protective cover layer 4.

FIG. 4 shows an extruded plastic profile 10 according to the invention which also comprises a profile body 2 with a base layer 6 deposited thereon.

An adhesion-promoting intermediate layer 11 is provided here as well which, however, is created through processing of the base layer 6 surface. This can be done, for example, by means of physical or chemical etching which roughens up or structures the surface. The thin film 3 is subsequently deposited on this intermediate layer 11, created through processing. A second adhesion-promoting intermediate layer 12 is then created through suitable mechanical, physical or chemical processing of the thin film 3 surface, e.g. also through etching, wherein the use of oxidation or fluoridation or the like is conceivable as well. It is important in this connection that the processing of the thin film surface for forming the intermediate surface occurs in such a way that the actual optical characteristics desired for the thin film are not influenced or not to a significant degree. The protective cover layer 4 is then deposited on the intermediate layer 12 created in this way. The layer system according to FIG. 4 also is a five-layer system, comprising a base layer 6, a first intermediate layer 11, a thin film 3, a second intermediate layer 12 and a protective cover layer 4, wherein the two intermediate layers 11, 12 in this case are not separate layers, but are layers created on the surface of the base layer and the thin film by means of a corresponding processing of these layers.

It must be noted here that the thin film in particular, as well as the adhesion-promoting layers, are very thin. The thickness of the thin film should be ≦5 μm, in particular ≦3 μm. The thickness of the intermediate layer between the thin film and the protective cover layer should also be in this range or below to avoid any influencing of the optics. Even lower layer thicknesses can be adjusted if the intermediate layers are created through processing of the layers positioned underneath. The base layer thickness can be optionally selected and should be selected so as to depend on the surface of the profile body. A sufficient thickness is required only for the protective cover layer 4 so that it can meet its protective function, in particular against mechanical influencing, wherein a thickness =1 mm is advantageous. The sectional views shown in the Figures are only meant as examples and do not reflect the actual thickness ratios.

The invention has been described in detail with respect to preferred embodiments, and it will now be apparent from the foregoing to those skilled in the art, that changes and modifications may be made without departing from the invention in its broader aspects, and the invention, therefore, as defined in the appended claims, is intended to cover all such changes and modifications that fall within the true spirit of the invention.

What is claimed is:

1. A method for making a plastic profile, comprising
depositing an inner thin film with a metallic appearance onto a surface of a flexible extruded plastic profile,
depositing an outer protective cover layer that is at least partially transparent onto the inner thin film,
wherein the inner thin film and the outer protective cover layer form a layer system to cover the flexible extruded plastic profile.

2. The method according to claim 1, wherein the depositing step includes depositing the inner thin film by one of chemical metallizing, galvanic coating, micro-particles deposition, vacuum vapor deposit, sputtering, thermal vapor deposition, and light-arc vapor deposition.

3. The method according to claim 1, wherein the depositing step includes depositing the inner thin film to at least partially cover the surface of the flexible extruded plastic profile.

4. The method according to claim 1, further comprising
forming an adhesion-promoting intermediate layer between the inner thin film and the outer protective cover layer.

5. The method according to claim 4, wherein the intermediate layer is formed as a separate intermediate layer.

6. The method according to claim 4, wherein the forming step includes forming the intermediate layer by mechanical, physical, or chemical processing of a surface of the inner thin film.

7. The method according to claim 6, wherein the forming step includes forming the intermediate layer by one of physical etching, chemical etching, oxidation, and fluoridation of the surface of the inner thin film.

8. The method according to claim 1, further comprising
forming a base layer on the outer surface of the flexible extruded plastic profile.

9. The method according to claim 8, wherein the forming step includes forming the base layer as a varnish layer or a 2-component varnish layer system that is deposited on the outer surface of the flexible extruded plastic profile by dipping.

10. The method according to claim 8, wherein the forming step includes forming the base layer as an extruded polymer layer that is deposited on the outer surface of the flexible extruded plastic profile by extrusion encasing.

11. The method according to claim 8, further comprising
forming an adhesion-promoting intermediate layer between the base layer and the inner thin film.

12. The method according to claim 11, wherein the forming step includes forming the intermediate layer as a separate intermediate layer.

13. The method according to claim 11, wherein the forming step includes forming the intermediate layer by one of mechanical, physical, and chemical processing of a surface of the base layer.

14. The method according to claim 13, wherein the forming step includes forming the intermediate layer by one of physical etching, chemical etching, oxidation, and fluoridation of the surface of the base layer.

15. The method according to claim 1, wherein the plastic profile comprises a plastic tube.
